(19) United States
(12) Patent Application Publication
(10) Pub. No.: US 2022/0252977 A1
(43) Pub. Date: Aug. 11, 2022

(54) A NEGATIVE TONE LIFT OFF RESIST COMPOSITION COMPRISING AN ALKALI SOLUBLE RESIN AND A PHOTO ACID GENERATOR, AND A METHOD FOR MANUFACTURING METAL FILM PATTERNS ON A SUBSTRATE.

(71) Applicant: Merck Patent GmbH, Darmstadt (DE)

(72) Inventors: Tomotsugu YANO, Kakegawa-shi (JP); Masahiko KUBO, Kakegawa-shi (JP); Tomohide KATAYAMA, Kakegawa-shi (JP)

(21) Appl. No.: 17/612,058

(22) PCT Filed: May 18, 2020
(86) PCT No.: PCT/EP2020/063782

§ 371 Date: Nov. 17, 2021

(30) Foreign Application Priority Data
May 20, 2019 (EP) 19175368.0

(51) Int. Cl. G03F 7/004; G03F 7/038

(52) U.S. Cl. CPC G03F 7/0045; G03F 7/0382

(57) ABSTRACT

An object is to provide a resist composition which can form fine resist patterns and keep them. Another object is to provide a resist layer with good sensitivity and/or resolution. And another object is to provide a negative tone lift off resist composition that removability of resist patterns made from the composition is good. [Solution] The present invention provides a negative tone lift off resist composition comprising an alkali soluble resin and a photo acid generator. And the present invention provides a method for manufacturing metal film patterns on a substrate. The present invention provides a method for a manufacturing a device comprising metal film patterns manufacturing method.

### TECHNICAL FIELD

The present invention relates to a negative tone lift off resist composition comprising an alkali soluble resin and a photo acid generator. And the present invention relates to a method for manufacturing metal film patterns on a substrate. And the present invention relates to a method for manufacturing a device comprising metal film patterns.

### BACKGROUND ART

Because there is a tendency to require more miniaturized apparatuses with higher performance, more fine patterning is required in devices (for example, semiconductor device, FPD device). Lithography technology using a photoresist (hereinafter, simply referred to as “resist”) is generally employed for fine processing. As exemplified in FIG. 1, a lift-off process to make an electrode is known, which is characteristically removing unnecessary electrode portions on the patterned resist layer. On the contrary, a typical electrode etching process uses resist patterns as a mask to remove (typically, by dry etching) electrode under the resist patterns to obtain designed electrode patterns.

Under these circumstance, specific negative tone photoresist compositions for forming a lift off-pattern were studied, which are applied on underlayer and are developed with the underlayer simultaneously (Patent Literature 1).

To achieve a high sensitivity with a good reverse taper profile, a negative photoresist composition is studied, comprising: an alkali-soluble binder resin; a halogen-containing first photo-acid generator; a triazine-based second photo-acid generator; a cross-linking agent having an alkoxy structure; and a solvent (Patent Literature 2).

To achieve shelf stability, high sensitivity, and a film retention (after development) of more than 95 percent to form a lift-off resist pattern of fully undercut profile, a lift-off resist composition is studied, comprising an alkali-soluble cellulose resin, though it is positive tone resist (Patent Literature 3).

### CITATION LIST

### Patent Literature

[Patent Literature 1] JP2005-37414A

[Patent Literature 2] US2011/0274853A

[Patent Literature 3] US2012/0129106A

### SUMMARY OF INVENTION

### Technical Problem

The inventors have found that there are still one or more considerable problems for which improvement are desired, as listed below; coatability is insufficient; solubility of a solute is insufficient; in the case the pattern sizes are small, it's difficult to obtain developed resist patterns with good shape and/or defects are found; in the case the pattern sizes are small, removability of the resist patterns is insufficient; yield is insufficient; sensitivity and/or resolution of the resist layer is insufficient; it's difficult to obtain a reverse taper profile.

Then, the inventors found that the invention described below solves at least one of these problems.

### Solution to Problem

The present invention provides a negative tone lift off resist composition comprising a single or plurality of (A) alkali soluble resin, and a single or plurality of (B) photo acid generator; wherein

(A) alkali soluble resin comprises (A1) resin and/or (A2) resin;

(B) photo acid generator comprises (B1) onium salt and/or (B2) sulfonyl compound;

With the proviso that (i) in case the negative tone lift off resist composition comprises a single of (A) alkali soluble resin, the negative tone lift off resist composition comprises a plurality of (B) photo acid generators, and (ii) in case the negative tone lift off resist composition comprises a single of (B) photo acid generator, the negative tone lift off resist composition comprises a plurality of (A) alkali soluble resins;

(A1) resin is represented by below formula (A1);

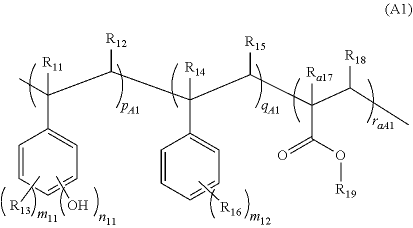

R₁₁, R₁₂, R₁₄, R₁₅, R₁₇ and R₁₈ are each independently hydrogen, C₁₋₆ alkyl, carboxyl, halogen or cyano, R₁₃ and Rig are each independently C₁₋₆ alkyl, C₁₋₆ alkoxy, halogen or cyano, R₁₉ is C₁₋₁₅ alkyl or C₁₋₁₅ alkoxy, wherein the alkyl portion of R₁₉ can form a saturated ring and/or an unsaturated ring, mu₁₁ is a number of 0-4, n₁₁ is a number of 1-3, m₁₁+n₁₁≤5, m₁₂ is a number of 0-5, p_{A1}, q_{A1} and r_{A1} are repeating numbers, [p_{A1}/(p_{A1}+q_{A1}+r_{A1})] is 30-98%, [q_{A1}/(p_{A1}+q_{A1}+r_{A1})] is 0-70%, [r_{A1}/(p_{A1}+q_{A1}+r_{A1})] is 0-70%;

(A2) resin is represented by below formula (A2);

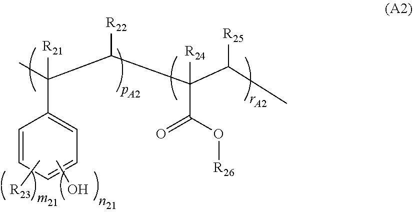

R₂₁, R₂₂, R₂₄ and R₂₅ are each independently hydrogen, C₁₋₆ alkyl, carboxyl, halogen or cyano, R₂₃ is C₁₋₆ alkyl, C₁₋₆ alkoxy, halogen or cyano, R₂₆ is C₁₋₁₅ alkyl or C₁₋₁₅ alkoxy, wherein the alkyl portion of R₂₆ can form a saturated ring and/or an unsaturated ring, m₂₁ is a number of 0-4, n₂₁ is a number of 1-3, m₂₁+n₂₁≤5, p_{A2} and r_{A2} are repeating numbers, [p_{A2}/(p_{A2}+r_{A2})] is 30-100%, [r_{A2}/(p_{A2}+r_{A2})] is 0-70%;

(B1) onium salt is represented by below formula (B1);

[B^{m+}cation][Bm^{m-}anion] (B1),

B^{m+} cation is represented by below formula (B1)-C1 and/or formula (B1)-C2, having m valences as whole, m=1-3;

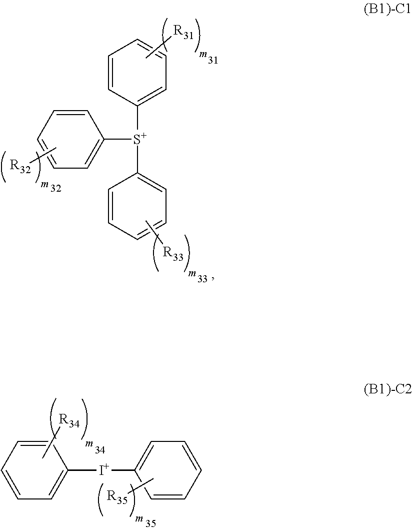

R₃₁, R₃₂, R₃₃, R₃₄ and R₃₅ are each independently C₁₋₆ alkyl, C₁₋₆ alkoxyl or C₆₋₁₂ aryl, m₃₁, m₃₂, m₃₃, m₃₄ and m₃₅ are each independently numbers of 0-3;

Bm^{m-} anion is represented by below formula (B1)-A1, (B1)-A2 and/or (B1)-A3;

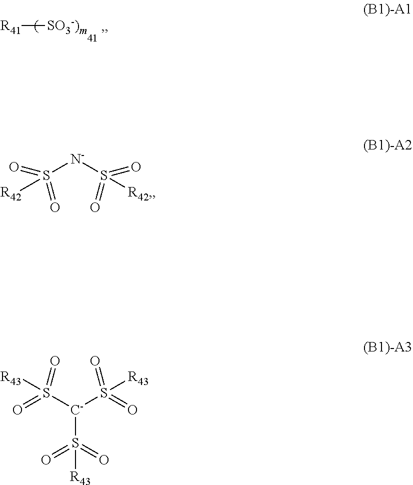

R₄₁, R₄₂ and R₄₃ are each independently C₆₋₁₂ aryl unsubstituted or substituted by C₁₋₆ alkyl, C₁₋₁₂ alkyl unsubstituted or substituted by halogen or carbonyl, m₄₁=1 or 2;

(B2) sulfonyl compound is represented by below formula (B2)-1 or (B2-2);

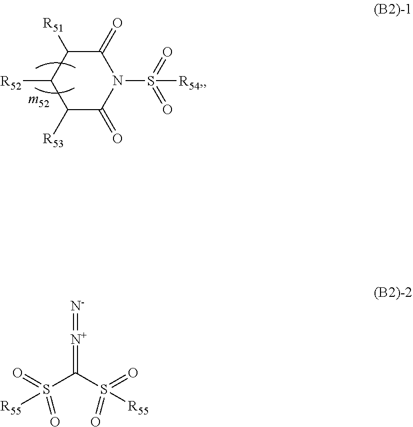

R₅₁, R₅₂ and R₅₃ are each independently hydrogen, C₁₋₆ alkyl, C₁₋₆ alkoxyl or C₆₋₁₂ aryl, alkyl portion of R₅₁, R₅₂ and R₅₃ can bind each other to constitute cycloalkyl or aryl,

m₅₂=0 or 1,

R₅₄ is C₁₋₆ alkyl unsubstituted or substituted by halogen,

R₅₅ are each independently C₅₋₁₂ cycloalkyl or C₆₋₁₂ aryl.

This invention provides a method for manufacturing a resist pattern, comprising: forming a coating of the negative tone lift off resist composition above a substrate; baking the resist composition to form a resist layer; exposing the resist layer; developing the resist layer to form resist patterns.

This invention provides a method for manufacturing a metal film pattern on a substrate, comprising: manufacturing a resist pattern; forming a metal film on the resist pattern; and removing the remaining resist pattern and metal film on them.

This invention provides a method for manufacturing a device, comprising a manufacturing method of a resist pattern or a metal film pattern on a substrate.

### Effects of the Invention

The negative tone lift off resist composition can exhibit a good coatability. The solutes in the composition can exhibit good solubility in solvent(s). Even if the pattern size is small, good shape of developed resist patterns made by the composition can be obtained and/or defects (e.g., pattern collapse) can be decreased. And even if the pattern size is small, clear removability of the resist patterns made by the composition can be obtained. High yield can be achieved. The resist layer obtained by the composition of the invention can exhibit a good sensitivity. The photoresist layer can have a good resolution. A resist pattern with a reverse taper profile can be obtained by the composition of the invention. Those are advantageous for more fine designed patterns for lift off process to make metal film patterns.

### BRIEF DESCRIPTION OF THE DRAWINGS

FIG. 1 is a schematic profile of a lift off process.

FIG. 2 is a schematic profile of an etching process.

FIG. 3 is an explanatory drawing of a mask design used for resist patterning.

FIG. 4 is an explanatory drawing of a mask design used for resist patterning.

### DESCRIPTION OF EMBODIMENTS

The above summary and the following details are provided for illustration of the present invention, and are not intended to limit the claimed invention.

Definitions

Throughout this specification, below defined symbols, units, abbreviations and terms have the meanings given in below definitions, descriptions and examples, unless explicitly limited or stated.

The use of the singular includes the plural, and the words “a”, “an” and “the” mean “at least one”. Furthermore, the use of the term “including”, as well as other forms such as “includes” and “included”, is not limiting. Also, terms such as “element” or “component” encompass both elements or components comprising one unit and elements or components that comprise more than one unit.

The term “and/or” refers to any combination of the any foregoing elements including using a single element.

When a numerical range is specified herein using “-”, “to” or “˜”, the numerical range includes both of the numbers indicated before and after “-”, “to” or “˜” and the unit is the same for the two numbers. For example, “5-25 mol %” means “5 mol % or more and 25 mol % or less”.

The terms such as “C_{x-y}”, “ Cₓ-C_{x-y}”, and “Cₓ” as used herein represent the number of carbon atoms in a molecule or substituent. For example, “C₁₋₆ alkyl” refers to an alkyl chain having 1-6 carbon atoms (such as methyl, ethyl, propyl, butyl, pentyl, hexyl and so on).

When a polymer as described herein has plural types of repeating units, these repeating units are copolymerized. The copolymerization may be any one selected from alternating copolymerization, random copolymerization, block copolymerization, graft copolymerization, and any combination of any of these. When a polymer or resin is represented by a chemical structure, n, m and so on put down with brackets means repeating numbers. The unit of temperatures as indicated herein is degree Celsius. For example, “20 degrees” means “20 degrees Celsius”.

Negative Tone Lift Off Resist Composition

This invention provides a negative tone lift off resist composition comprising a single or plurality of (A) alkali soluble resin, and a single or plurality of (B) photo acid generator. The negative tone resist composition of the invention is useful for a lift off process, wherein metal film portions formed on a developed resist layer (resist pattern walls) are removed in a later step to obtain metal film patterns. Because the composition of this invention is a negative tone resist, the resist layer made by the composition has the property that the exposed portion of the layer shows increased resistance against dissolution by a developer, and that unexposed portion will be dissolved by the developer.

The composition of this invention satisfies the conditions that (i) in case the negative tone lift off resist composition comprises a single of (A) alkali soluble resin, the negative tone lift off resist composition comprises a plurality of (B) photo acid generators, and (ii) in case the negative tone lift off resist composition comprises a single of (B) photo acid generator, the negative tone lift off resist composition comprises a plurality of (A) alkali soluble resins. It is accepted that the composition of this invention comprises a plurality of (A) alkali soluble resin and a plurality of (B) photo acid generators at the same time. It can be said that such composition is excluded from the scope of the invention which satisfies (iii) the alkali soluble resin in the composition consists of a single alkali soluble resin, and (iv) the photo acid generator in the composition consists of a single photo acid generator, at the same time.

Alkali Soluble Resin

The composition of this invention comprises a single or plurality of (A) alkali soluble resin. The (A) alkali soluble resin comprises (A1) resin and/or (A2) resin. This resin is preferably an alkali soluble binder resin. And this resin preferably comprises a novolac-based polymer or a polyhydroxystyrene-based polymer. A resin comprised by the composition of the invention is preferably a random copolymer or block copolymer, more preferably a random copolymer.

For example, the (A) alkali soluble resin can comprises a plurality of (A1) resin and no (A2) resin.

It is one embodiment of the invention that the mass ratio of the (A) alkali soluble resin to the total mass of the negative tone lift off resist composition is 5-50 mass % (preferably 10-30 mass %, more preferably 10-25 mass %). When the thickness of the coating made from the negative tone lift off resist composition is on or more than 1.0 μm, the above mass ratio is preferably 15-30 mass % (more preferably 15-25 mass %, further preferably 18-22 mass %). When the thickness of the coating made from the composition of the invention is less than 1.0 μm, the above mass ratio is preferably 5-15 mass % (more preferably 5-14 mass %, further preferably 10-14 mass %). The formed resist coating thickness can be extended by adding more solid components (can be mainly occupied by (A) alkali soluble resin) in the composition.

As aforementioned, the composition of this invention can comprise plural (A) alkali soluble resins. Without wishing to be bound by theory, it is believed that it is good to include plural (A) alkali soluble resins in the composition, because the alkali resolution rate of the resist layer can be set appropriately to exhibit a good sensitivity, a good resolution and/or good pattern shapes.

In the present application, the weight average molecular weight (Mw) can be measured by gel permeation chromatography (GPC). In a suitable example of this measurement, a GPC column is set to 40 degrees Celsius; 0.6 mL/min of tetrahydrofuran is used as an elution solvent; and monodisperse polystyrene is used as a standard.

As one aspect of the invention, the weight average molecular weight (Mw) of the (A) alkali soluble resin of the composition of the invention is preferably 2,000 to 100,000, more preferably 3,000 to 50,000, further preferably 4,000 to 20,000, further more preferably 5,000 to 15,000.

(A1) resin

(A1) resin is represented by below formula (A1).

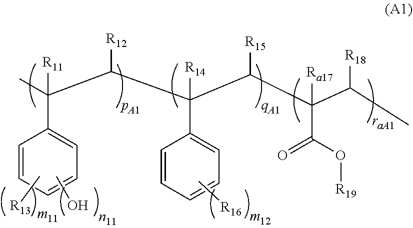

R₁₁, R₁₂, R₁₄, R₁₅, R₁₇ and R₁₈ are each independently hydrogen, C₁₋₆ alkyl, carboxyl, halogen or cyano; preferably hydrogen or methyl; more preferably hydrogen. It is one embodiment of the invention that R₁₇ is methyl.

R₁₃ and Rig are each independently C₁₋₆ alkyl, C₁₋₆ alkoxy, halogen or cyano; preferably methyl, ethyl, isopropyl, t-butyl or fluorine; more preferably methyl or t-butyl.

R₁₉ is C₁₋₁₅ alkyl or C₁₋₁₅ alkoxy. Alkyl portion of R₁₉ can form a saturated ring and/or an unsaturated ring. It is one embodiment of the invention that R₁₉ is C₁₋₁₅ alkyl. Alkyl portion of R₁₉ is preferably a branched or cyclic structure, more preferably a branched structure. R₁₉ is preferably methyl, ethyl, isopropyl, t-butyl, cyclopentyl, methylcyclopentyl, ethylcyclopentyl, methylcyclohexyl, ethylcyclohexyl, methyladamantyl or ethyladamantyl; more preferably t-butyl, ethylcyclopentyl, methycyclolhexyl, or ethyladamantyl; further preferably t-butyl.

m₁₁ is a number of 0-4. It can be one embodiment of the invention that (A) alkali soluble resin doesn't comprise (A2) resin and comprise two (A1) resins one half each; p_{A1}=100%, m₁₁=1 in one (A1) resin; and p_{A1}=100%, m₁₁=2 in the other (A1) resin. In this case, m₁₁=1.5. Otherwise specifically stated, same in herein later.

m₁₁ is preferably 0, 1, 2, 3 or 4; more preferably 0, 1 or 2; further preferably 0.

n₁₁ is a number of 1-3; more preferably 1 or 2; further preferably 1.

m₁₁+n₁₁≤5.

m₁₂ is a number of 0-5; preferably 0, 1, 2, 3 or 4; more preferably 0, 1 or 2; further preferably 0.

p_{A1}, q_{A1} and r_{A1} are repeating numbers.

[p_{A1}/(p_{A1}+q_{A1}+r_{A1})] is 30-98%; preferably 50-95%; more preferably 70-95%; further preferably 70-90%.

[q_{A1}/(p_{A1}+q_{A1}+r_{A1})] is 0-70%; preferably 0-40%; more preferably 5-40%; further preferably 10-40%.

[r_{A1}/(p_{A1}+q_{A1}+r_{A1})] is 0-70%; preferably 0-40%.

It is preferable that q_{A1} and r_{A1} don't take 0% at the same time. It is one preferable embodiment of the invention that [r_{A1}/(p_{A1}+q_{A1}+r_{A1})]=0%.

The (A1) resin of the invention may comprise or may not comprise a repeating unit other than units described in formula (A1) and defined above. It is preferable embodiment that the (A1) resin of the composition of the invention does not comprise a repeating unit other than the units described in formula (A1) and defined above.

Exemplified embodiments of (A1) resin are described below, but only for illustrative purpose.

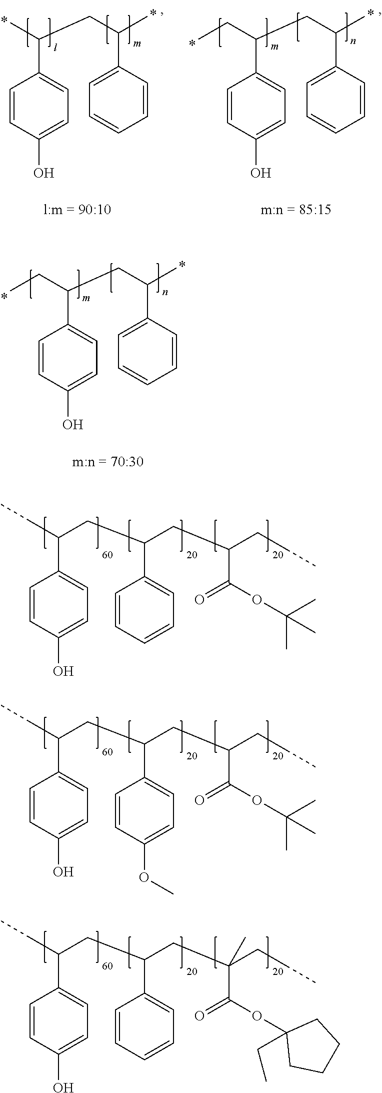

As one aspect of the invention, the weight average molecular weight (Mw) of the (A1) resin of the composition of the invention is preferably 5,000 to 100,000, more preferably 5,000 to 50,000, further preferably 5,000 to 20,000, further more preferably 8,000 to 15,000.

The mass ratio of the (A1) resin to the sum of (A) alkali soluble resin is preferably 30-100 mass %, more preferably 40-100 mass %, further preferably 40-80 mass %. It is one embodiment of the invention that the (A) alkali soluble resin comprises not (A2) resin but (A1) resin.

(A2) Resin

(A2) resin is represented by below formula (A2).

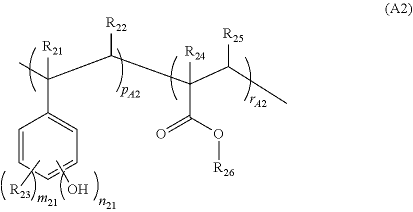

R₂₁, R₂₂, R₂₄ and R₂₅ are each independently hydrogen, C₁₋₆ alkyl, carboxyl, halogen or cyano; preferably hydrogen or methyl; more preferably hydrogen. It is one embodiment of the invention that R₂₄ is methyl. R₂₃ is C₁₋₆ alkyl, C₁₋₆ alkoxy, halogen or cyano; preferably methyl, ethyl, isopropyl, t-butyl or fluorine; more preferably methyl or t-butyl. R₂₆ is C₁₋₁₅ alkyl or C₁₋₁₅ alkoxy. Alkyl portion of R₂₆ can form a saturated ring and/or an unsaturated ring. It is one embodiment of the invention that R₂₆ is C₁₋₁₅ alkyl. The alkyl portion of R₂₆ is preferably a branched or cyclic structure, more preferably a branched structure. R₂₆ is preferably methyl, ethyl, isopropyl, t-butyl, cyclopentyl, methylcyclopentyl, ethylcyclopentyl, methylcyclohexyl, ethylcyclohexyl, methyladamantyl or ethyladamantyl; more preferably t-butyl, ethylcyclopentyl, methycyclolhexyl, or ethyladamantyl; further preferably t-butyl.

m₂₁ is a number of 0-4; preferably 0, 1, 2, 3 or 4; more preferably 0, 1 or 2; further preferably 0.

n₂₁ is a number of 1-3; more preferably 1 or 2; further preferably 1.

m₂₁+n₂₁≤5.

p_{A2} and r_{A2} are repeating numbers.

[p_{A2}/(p_{A2}+r_{A2})] is 30-100%; preferably 50-100%; more preferably 60-100%; further more preferably 100%.

[r_{A2}/(p_{A2}+r_{A2})] is 0-70%; more preferably 0-50%; more preferably 0-40%; further preferably 0%.

The (A2) resin of the invention may comprise or may not comprise a repeating unit other than the units described in formula (A2) and defined above. It is a preferable embodiment that the (A2) resin of the composition of the invention does not comprise a repeating unit other than the units described in formula (A2) and defined above.

Exemplified embodiments of (A2) resin are described below, but only for illustrative purpose.

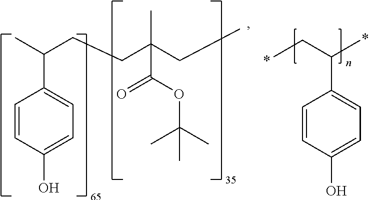

As one aspect of the invention, the weight average molecular weight (Mw) of the (A2) resin of the composition of the invention is preferably 2,000 to 20,000; more preferably 4,000 to 20,000; further preferably 5,000 to 10,000.

The mass ratio of the (A2) resin to the sum of (A) alkali soluble resin is preferably 10-100 mass %, more preferably 20-100 mass %, further preferably 20-50 mass %. It is one embodiment of the invention that the (A) alkali soluble resin comprises not (A1) resin but (A2) resin.

(B) Photo Acid Generator

The composition of this invention comprises a single or a plurality of (B) photo acid generator (can be denoted as PAG hereinafter). At radiation exposed portions of a negative tone resist composition, PAG receive radiation and generate acid, which catalyze cross linking reactions of resin and, a cross linker if present.

The (B) photo acid generator comprises a (B1) onium salt and/or a (B2) sulfonyl compound. For example, the (B) PAG can comprise a plurality of (B1) onium salts and no (B2) sulfonyl compound.

It is one embodiment of this invention that the mass ratio of (B) photo acid generator to the mass of (A) alkali soluble resin is 1-20 mass %; preferably 1-15 mass %; more preferably 1-10 mass %. For the sake of clarity it is noted that throughout this application in the case the composition of the invention comprises a plurality of (B) PAGs, the mass ratio of (B) PAG refers to the sum of mass ratios of the plurality of (B) PAGs. For the sake of clarity it is noted that throughout this application in the case that the composition of the invention comprises a plurality of (A) alkali soluble resins, the mass ratio of (A) alkali soluble resin refers to the sum of mass ratios of the plurality (A) alkali soluble resins.

As aforementioned, the composition of this invention can comprise plural (B) PAGs. Without wishing to be bound by theory, it is believed that it is good to include plural (B) PAGs in the composition, because resolution and/or pattern shapes can be appropriately set.

(B1) Onium Salt

The (B1) onium salt is represented by below formula (B1).

[B^{m+}cation] [B^{m-}anion] (B1)

The B^{m+}cation is represented by below formula (B1)-C1 and/or formula (B1)-C2. The B^{m+}cation has m valences as whole.

m=1-3; preferably 1, 2 or 3; more preferably 1 or 2; further preferably 1.

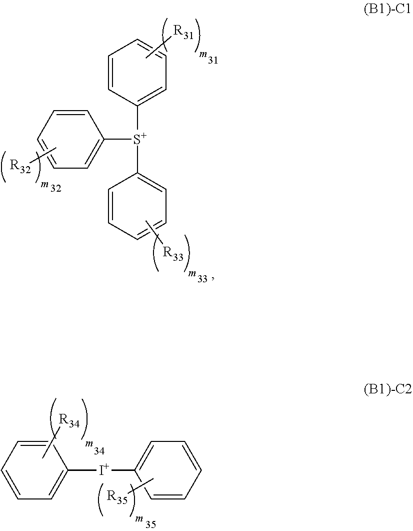

R₃₁, R₃₂, R₃₃, R₃₄ and R₃₅ are each independently C₁₋₆ alkyl, C₁₋₆ alkoxyl or C₆₋₁₂ aryl; preferably methyl, ethyl, t-butyl, 1,1-dimethylpropyl, methoxy, or ethoxy; more preferably methyl, t-butyl, 1,1-dimethylpropyl, or methoxy; further preferably t-butyl.

m₃₁, m₃₂, m₃₃, m₃₄ and m₃₅ are each independently numbers of 0-3; preferably each independently 0 or 1; more preferably 0. It is one embodiment of the invention that m₃₁, m₃₂, m₃₃, m₃₄ and m₃₅ are each independently numbers of 1.

Exemplified embodiments of a B^{m+} cation are described below, but only for illustrative purpose.

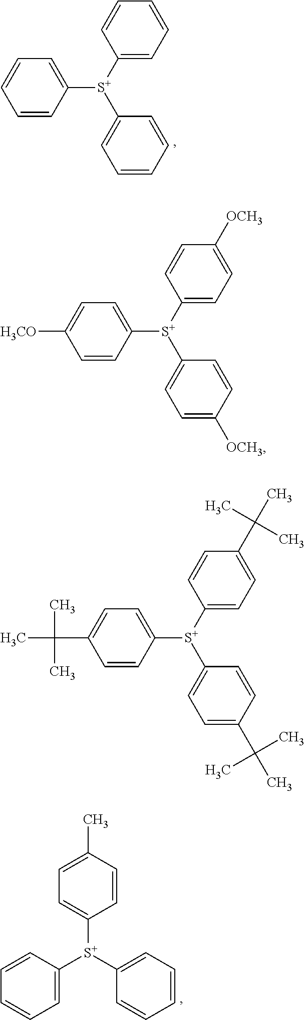 [SMILES: c1ccc([S+](c2ccccc2)c2ccccc2)cc1 ; COc1ccc([S+](c2ccc(OC)cc2)c2ccc(OC)cc2)cc1 ; CC(C)(C)c1ccc([S+](c2ccc(C(C)(C)C)cc2)c2ccc(C(C)(C)C)cc2)cc1 ; Cc1ccc([S+](c2ccccc2)c2ccccc2)cc1]

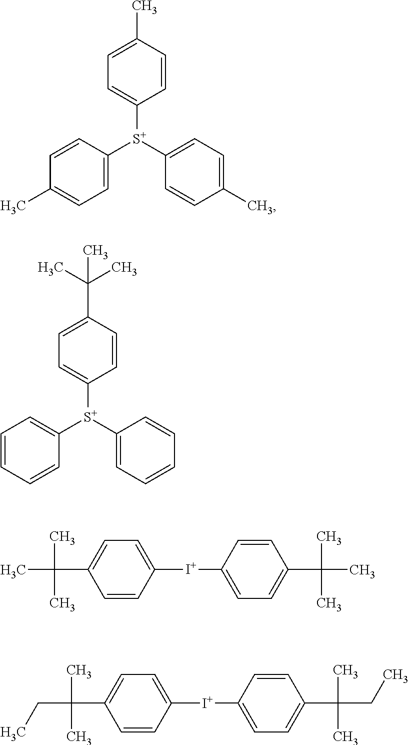

The B^{m-} anion is represented by below formula (B1)-A1, (B1)-A2 and/or (B1)-A3.

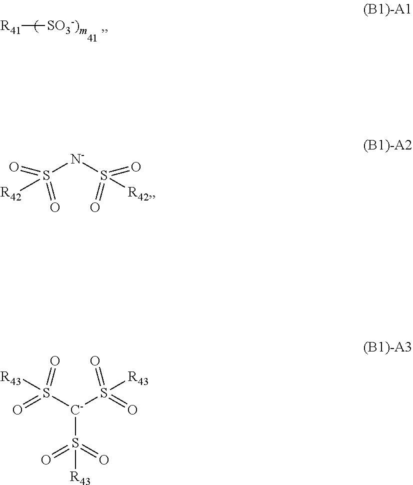

R₄₁, R₄₂ and R₄₃ are each independently C₆₋₁₂ aryl unsubstituted or substituted by C₁₋₆ alkyl, C₁₋₁₂ alkyl unsubstituted or substituted by halogen or carbonyl; preferably C₁₋₆ alkyl unsubstituted or substituted by halogen; more preferably C₁₋₄ alkyl substituted by halogen; further preferably C₁ or C₄ alkyl substituted by halogen. In here halogen is preferably fluorine. As one embodiment of the invention, an alkyl portion of R₄₁, R₄₂ or R₄₃ can bind internally or each other to form a saturated cyclic hydrocarbon ring. As preferable embodiment, an alkyl portion of R₄₁, R₄₂ or R₄₃ doesn't bind internally or each other to form a saturated cyclic hydrocarbon ring. It is preferable embodiment that all hydrogen in C₁₋₆ alkyl are substituted by halogen.

m₄₁=1 or 2; preferably 1. When m₄₁=2, R₄₁ is a divalent linker.

Exemplified embodiments of a B^{m-}anion are described below, but only for illustrative purpose.

CF₃SO³⁻, C₄F₉SO³⁻, C₃F₇SO³⁻,

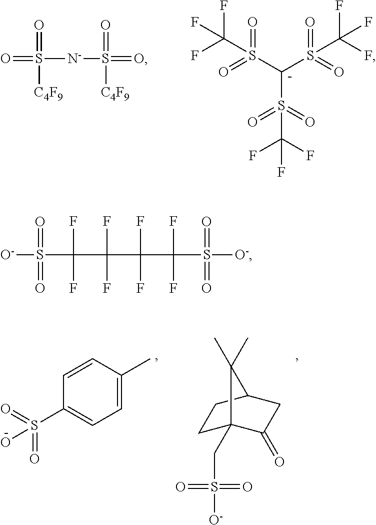

For example, below onium salt is one example of formula (B1). B^{m+}cation is represented by (B1)-C1, and has m=2 valences as whole. B^{m-}anion is represented by formula (B1)-A1, and has m=2 valences as whole. m₄₁=2.

R₄₁ is C₄ alkylene substituted by fluorine.

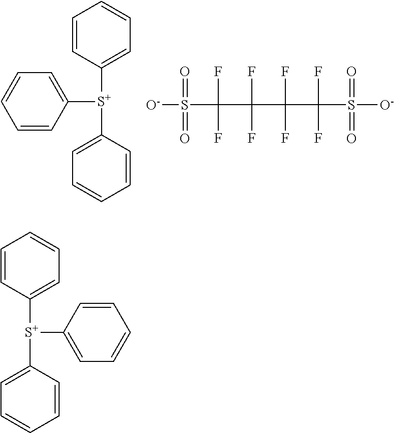 [SMILES: c1ccc([S+](c2ccccc2)c2ccccc2)cc1 ; O=S(=O)([O-])C(F)(F)C(F)(F)C(F)(F)C(F)(F)S(=O)(=O)[O-] ; c1ccc([S+](c2ccccc2)c2ccccc2)cc1]

(B2) Sulfonyl Compound

The (B2) sulfonyl compound is represented by below formula (B2)-1 or (B2-2).

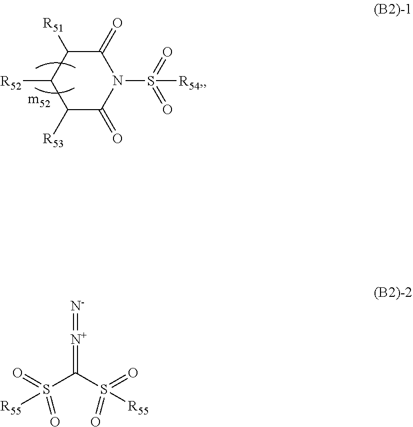

R₅₁, R₅₂ and R₅₃ are each independently hydrogen, C₁₋₆ alkyl, C₁₋₆ alkoxyl or C₆₋₁₂ aryl; preferably C₁₋₆ alkyl. Alkyl portion of R₅₁, R₅₂ and R₅₃ can bind to each other to constitute cycloalkyl or aryl.

m₅₂=0 or 1; preferably 0. It is one preferable embodiment of this invention that m₅₂=1.

R₅₄ is C₁₋₆ alkyl unsubstituted or substituted by halogen; preferably C₁₋₄ alkyl substituted by fluorine.

R₅₅ are each independently C₅₋₁₂ cycloalkyl or C₆₋₁₂ aryl; preferably C₅₋₁₂ cycloalkyl; more preferably C₆ cycloalkyl.

Exemplified embodiments of (B2) sulfonyl compound are described below, but only for illustrative purpose.

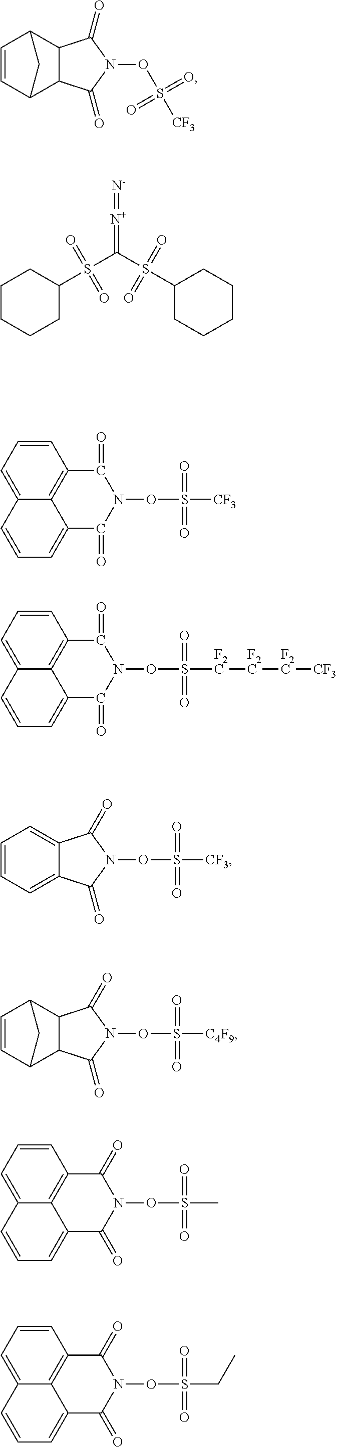

(C) Solvent

The composition of this invention can comprise (C) solvent. It is one embodiment of this invention that the (C) solvent comprise for example water and organic solvent. It is preferable embodiment of this invention that (C) solvent is selected from the group consisting of aliphatic hydrocarbon solvent, aromatic hydrocarbon solvent, monoalcohol solvent, polyol solvent, ketone solvent, ether solvent, ester solvent, nitrogen-containing solvent, sulfur-containing solvent, and any combination of any of these.

Examples of the (C) solvents include: aliphatic hydrocarbon solvents such as n-pentane, i-pentane, n-hexane, i-hexane, n-heptane, i-heptane, cyclohexane, and methylcyclohexane; aromatic hydrocarbon solvents such as benzene, toluene, xylene, ethylbenzene, trimethylbenzene, methylethylbenzene, n-propylbenzene, i-propylbenzene, diethylbenzene, and i-butylbenzene,; monoalcohol solvents such as methanol, ethanol, n-propanol, i-propanol, n-butanol, i-butanol, sec-butanol, t-butanol, n-pentanol, i-pentanol, 2-methylbutanol, 2-ethylhexanol, n-nonyl alcohol, 2, 6-dimethylheptanol-4, n-decanol, cyclohexanol, benzyl alcohol, phenylmethylcarbinol, diacetone alcohol, and cresol; polyol solvents such as ethylene glycol, propylene glycol, 1,3-butylene glycol, diethylene glycol, dipropylene glycol, triethylene glycol, tripropylene glycol, and glycerin; ketone solvents such as acetone, methyl ethyl ketone, methyl n-propyl ketone, methyl n-butyl ketone, diethyl ketone, trimethylnonanone, cyclohexanone, cyclopentanone, methylcyclohexanone, 2,4-pentanedione, acetonylacetone, acetophenone, and fenchone; ether solvents such as ethyl ether, i-propyl ether, n-butyl ether, n-hexyl ether, 2-ethylhexyl ether, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents such as diethyl carbonate, methyl acetate, ethyl acetate, γ-butyrolactone, γ-valerolactone, n-propyl acetate, i-propyl acetate, n-butyl acetate, i-butyl acetate, n-butyl propionate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, and propylene glycol monopropyl ether acetate; nitrogen-containing solvents such as N-methylformamide; and sulfur-containing solvents such as dimethyl sulfide. Any mixture of any of these solvents can also be used.

In particular, cyclohexanone, cyclopentanone, propylene glycol monomethyl ether, propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate, propylene glycol monoethyl ether acetate, propylene glycol monopropyl ether acetate, γ-butyrolactone, ethyl lactate, and any mixture of any of these are preferred in terms of the storage stability of the solution.

In terms of the coatability and/or solubility of the solute, propylene glycol monomethyl ether, propylene glycol 1-monomethyl ether 2-acetate, ethyl lactate, and a mixture of any two solvents selected therefrom are preferred. For this purpose, propylene glycol 1-monomethyl ether 2-acetate is more preferable as (C) solvent.

The (C) solvents preferably comprise an organic solvent, and the amount of water in the composition is preferably 0.1 mass % or less and further preferably 0.01 mass % or less. Given the relationship with another layer or coating, it is preferable for the (C) solvent to be free of water. As one aspect of the present invention, the amount of water in the composition is preferably 0.00 mass %.

It is one embodiment of this invention that the mass ratio of the (C) solvent to the total mass of the negative tone lift off resist composition is 30-94 mass %; preferably 50-94 mass %; more preferably 70-94 mass %; further preferably 75-90 mass %.

(D) Cross Linker

The composition of this invention can comprise (D) cross linker (can be denoted as X linker, hereinafter). In a negative tone resist, resin and a cross linker(s) causes cross linking reactions by e.g., the heat of a post-exposure bake. And the solubility of the exposed portion of the resist layer changes.

It is one embodiment of this invention that (D) cross linker comprises at least one selected from the group consisting of aryl compound, melamine compound, guanamine compound, glycoluril compound, urea compound epoxy compound; thioepoxy compound, isocyanate compound, azide compound and alkenyl compound; and each compound is unsubstituted or substituted by at least one group selected from a hydroxyl group, a methylol group, an alkoxymethyl group, and an acyloxymethyl group.

The composition of this invention can comprise a single or plurality of (D) cross linker. It is one aspect of this invention that the composition comprises a plurality of (D) cross linkers, for example comprising two species of (D) cross linkers.

It is one embodiment of this invention that the mass ratio of (D) cross linker to the mass of (A) alkali soluble resin is 1-20 mass %; preferably 3-20 mass %; more preferably 5-15 mass %.

The (D) cross linker of the invention can comprise (D1) cross linker represented by formula (D1) and/or (D2) cross linker represented by formula (D2). It is one embodiment of the invention that the composition of the invention comprises a single of (D2) cross linker and no other cross linker.

In addition to exemplified embodiments described in later as represented by formula (D1) or (D2), below described compounds are other exemplified embodiments, but only for illustrative purpose.

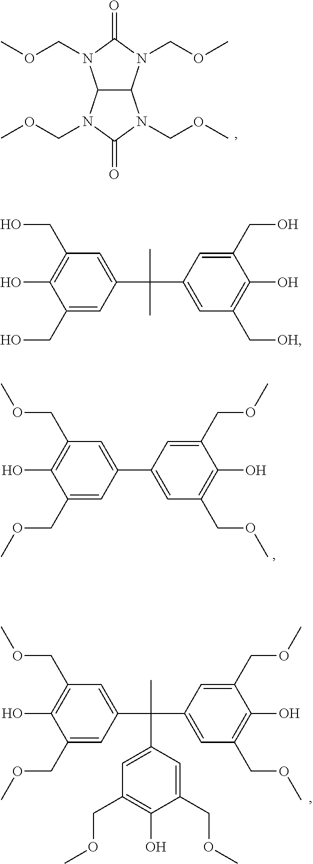

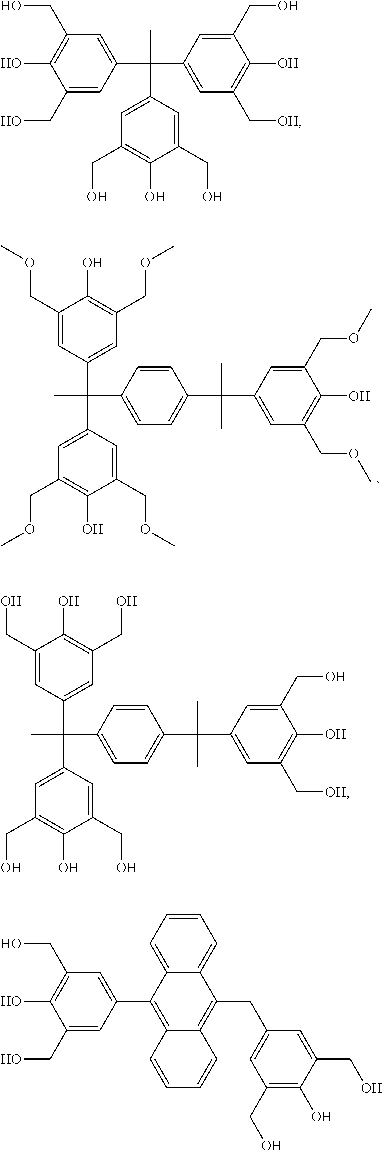

(D1) Cross Linker

The (D1) cross linker is represented by formula (D1).

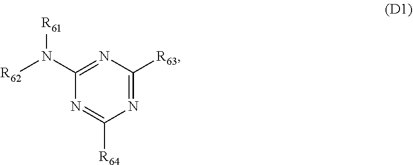

R₆₁ is C₂₋₈ alkoxylalkyl; preferably C₂₋₄ methoxyl alkyl; more preferably —CH₂-O—CHs.

R₆₂ is C₂₋₈ alkoxylalkyl; preferably C₂₋₄ methoxyl alkyl, more preferably —CH₂-O—CH₃.

R₆₃ is C₆₋₁₀ aryl unsubstituted or substituted by C₁₋₆ alkyl, C₁₋₈ alkyl unsubstituted or substituted by C₁₋₆ alkyl, or —NR₆₁R₆₂. C₆₋₁₀ aryl of R₆₃ is preferably phenyl or naphthyl, more preferably phenyl. C₁₋₈ alkyl of R₆₃ is preferably methyl, ethyl, propyl, butyl, pentyl, or hexyl, more preferably methyl, or butyl. C₁₋₆ alkyl substituting C₆₋₁₀ aryl or C₁₋₈ alkyl of R₆₃ is preferably methyl, ethyl, isopropyl, or butyl, more preferably methyl. Unsubstituted C₆₋₁₀ aryl and C₁₋₈ alkyl of R₆₃ are further preferable. Further more preferably R₆₃ is —NR₆₁R₆₂. Definitions and preferred embodiments of R₆₁ and R₆₂ are each independently same to described above.

R₆₄ is C₆₋₁₀ aryl unsubstituted or substituted by C₁₋₆ alkyl, C₁₋₈ alkyl unsubstituted or substituted by C₁₋₆ alkyl, or —NR₆₁R₆₂. C₆₋₁₀ aryl of R₆₄ is preferably phenyl or naphthyl, more preferably phenyl. C₁₋₈ alkyl of R₆₄ is preferably methyl, ethyl, propyl, butyl, pentyl, or hexyl, more preferably methyl, or butyl. C₁₋₆ alkyl substituting C₆₋₁₀ aryl or C₁₋₈ alkyl of R₆₄ is preferably methyl, ethyl, isopropyl, or butyl, more preferably methyl. Unsubstituted C₆₋₁₀ aryl and C₁₋₈ alkyl of R₆₄ are further preferable. Further more preferably R₆₄ is —NR₆₁R₆₂. Definitions and preferred embodiments of R₆₁ and R₆₂ are each independently same to described above.

Exemplified embodiments of (D1) cross linker represented by formula (D1) are described below, but only for illustrative purpose.

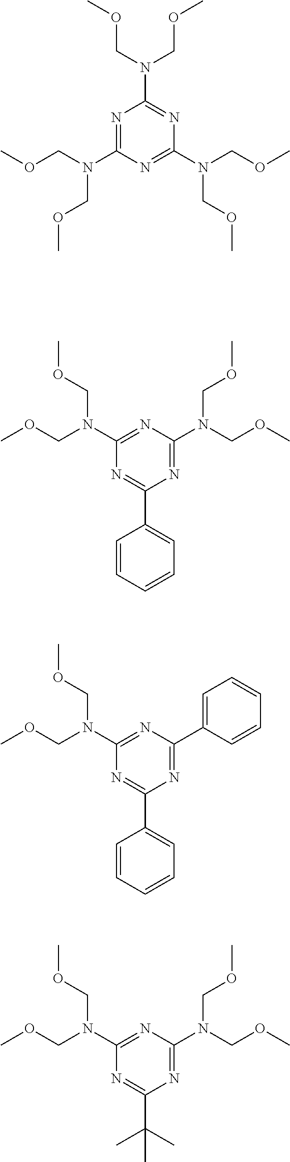

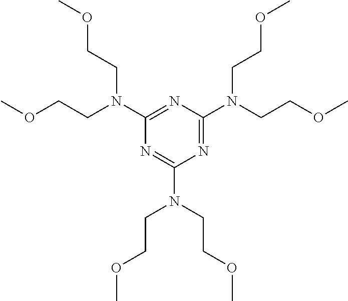

As one aspect of the invention, the mass ratio of (D1) cross linker to the mass of (A) alkali soluble resin is preferably 0.10-8 mass %; more preferably 0.5-5 mass %; further preferably 0.5-3 mass %.

(D2) Cross Linker

The (D2) cross linker is represented by formula (D2).

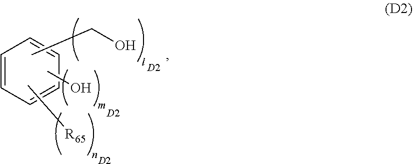

R₆₅ is C₁₋₂₀ alkyl unsubstituted or substituted by C₁₋₆ alkyl. C₁₋₂₀ alkyl of R₆₅ can be linear alkyl or branched alkyl. C₁₋₂₀ alkyl of R₆₅ is preferably C₁₋₁₀ alkyl, more preferably methyl, ethyl, propyl, butyl, pentyl, hexyl, heptyl, octyl, or —C(CH₃)₂—CH₂—C(CH₃)₃, further preferably —C(CH₃)₂—CH₂-C(CH₃)₃. C₁₋₆ alkyl substituting C₁₋₂₀ alkyl of R₆₅ is preferably methyl, ethyl, isopropyl, or butyl, more preferably methyl. Unsubstituted C₁₋₂₀ alkyl of R₆₅ is further preferable.

I_{D2} is 1, 2, 3 or 4; preferably 2 or 3; more preferably 2.

m_{D2} is 0, 1 or 2; preferably 0 or 1; more preferably 1.

n_{D2} is 0, 1 or 2; preferably 1.

I_{D2}+m_{D2}+n_{D2}≤6.

Exemplified embodiments of (D2) cross linker represented by formula (D2) are described below, but only for illustrative purpose.

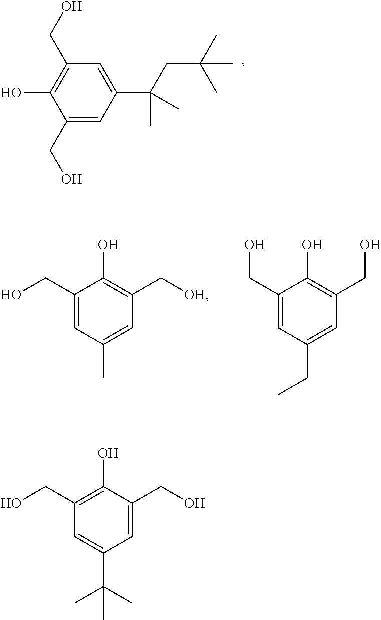 [SMILES: CC(C)(C)CC(C)(C)c1cc(CO)c(O)c(CO)c1 ; Cc1cc(CO)c(O)c(CO)c1 ; CCc1cc(CO)c(O)c(CO)c1 ; CC(C)(C)c1cc(CO)c(O)c(CO)c1]

As one aspect of the invention, the mass ratio of (D2) cross linker to the mass of (A) alkali soluble resin is preferably 0.50-40 mass %; more preferably 1-20 mass %; further preferably 5-15 mass %.

As one aspect of the present invention, the resist coating made by the composition of this invention with any one of the above amounts of cross linkers can exhibit good pattern shape and removability.

Additive

The composition of this invention can further comprise another additive.

Such additive can be selected from the group consisting of a quencher, a surfactant, dye, a contrast enhancer, acid, a radical generator, an agent for enhancing adhesion to substrates, base, a surface leveling agent, and an anti-foaming agent.

As one aspect of the invention, the mass ratio of other additives to the mass of (A) alkali soluble resin is preferably 0.05-10 mass %; more preferably 0.10-5 mass %; further preferably 0.10-2 mass %. It is one embodiment of the invention that the composition of the invention contains none (0 mass %) of these additives, otherwise specifically stated below.

As a dye monomeric dye and azo dye can be embodiment of the invention. Dye described on WO2001/61410 are other embodiments. As a dye, 9-Antracenemethanol is preferable embodiment of the invention.

Quencher

It is possible to add a quencher in the composition of the invention to improve properties such as the resist pattern shapes and the long term stability (the post exposure stability of the latent image formed by the pattern-wise exposure of the resist layer). As a quencher, an amine is preferred, and more specifically, a secondary aliphatic amine or tertiary aliphatic amine can be used. Here, an aliphatic amine refers to C₂₋₉ alkyl or C₂₋₉ alkyl alcohol amine. A single or plurality of alkylene in the alkyl portion of it can be substituted by an ether linker(s). Tertiary aliphatic amines with an C₃₋₆ alkyl alcohol is more preferred.

Exemplified embodiments of the quencher include trimethylamine, diethylamine, triethylamine, di-n-propylamine, tri-n-propylamine, triisopropylamine, tributylamine, tripentylamine, trioctylamine, diethanolamine, N,N-Dicyclohexylmethylamine, triethanolamine, and tris[2-(2-methoxyethoxy)ethyl]amine. triethanolamine and tris[2-(2-methoxyethoxy)ethyl]amine are more preferred.

It is one embodiment of the invention that the mass ratio of the quencher to the mass of (A) alkali soluble resin is preferably 0.05-5 mass %; more preferably 0.10-2 mass %; further preferably 0.10-1 mass %.

Surfactant

The composition of the invention can comprise a surfactant, which is useful for decreasing pin hole or striation in a coating, and for increasing coatability and/or solubility of a composition.

It is one embodiment of the invention that the mass ratio of the surfactant to the mass of (A) alkali soluble resin is preferably 0.01-10 mass %; more preferably 0.05-5 mass %; further preferably 0.05-2 mass %.

Examples of the surfactant include: polyoxyethylene alkyl ether compounds such as polyoxyethylene lauryl ether, polyoxyethylene stearyl ether, and polyoxyethylene oleyl ether; polyoxyethylene alkylaryl ether compounds such as polyoxyethylene octylphenol ether and polyoxyethylene nonylphenol ether; polyoxyethylene-polyoxypropylene block copolymer compounds; sorbitan fatty acid ester compounds such as sorbitan monolaurate, sorbitan monopalmitate, sorbitan monostearate, sorbitan trioleate, and sorbitan tristearate; and polyoxyethylene sorbitan fatty acid ester compounds such as polyoxyethylene sorbitan monolaurate, polyoxyethylene sorbitan monopalmitate, polyoxyethylene sorbitan monostearate, and polyoxyethylene sorbitan tristearate. Other examples of the surfactant include: fluorosurfactants such as EFTOP (trade name) EF301, EF303, and EF352 (Tohkem Products Corp.), MEGAFACE (trade name) F171, F173, R-08, R-30, and R-2011 (DIC Corp.), Fluorad FC430 and FC431 (Sumitomo 3M Ltd.), AsahiGuard (trade name) AG710 (Asahi Glass Co., Ltd.), and SURFLON S-382, SC101, SC102, SC103, SC104, SC105, and SC106 (Asahi Glass Co., Ltd.); and organosiloxane polymers such as KP341 (Shin-Etsu Chemical Co., Ltd.).

Lift Off Process

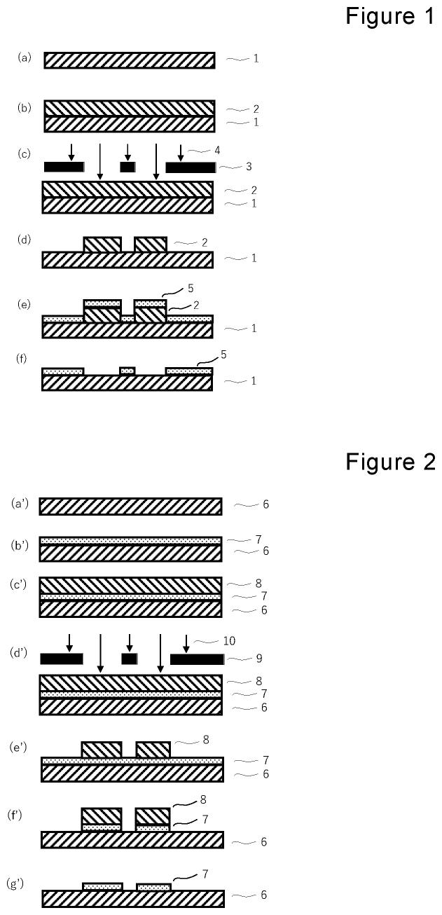

One exemplary process embodiment of the lift off patterning process is illustrated in a schematic diagram of FIG. 1. As shown in (a), a substrate is prepared, and then the resist composition is applied on the substrate and obtained as resist layer (shown in (b)). Next, exposure with light radiation through a designed mask as shown in (c). Then the resist layer is developed to form resist patterns as shown in (d). The resist patterns have walls and trenches.

For the later removing process, a resist pattern with a reverse taper profile is preferable. For example, the resist patterns can have such a good reverse taper profile that the substrate and the side of resist pattern wall preferably form an angle of less than 90 degrees (more preferably on or more than 55 degrees and less than 90 degrees, further preferably 55-80 degrees). The angle can be measured by a cross section photo by SEM. Then, a metal is applied (preferably deposited) on the resist patterns to form a metal film as shown in (e). The metal film is preferably an electrode. The metal film is formed on the resist pattern walls and trenches. It is preferable that the resist layer has sufficient thickness to make a gap between the metal film on the wall and the trench so that resist layer remover can invade through the gap.

And the resist patterns and metal film on them are removed as shown in (f) (preferably removed by a resist layer remover solution) to obtain metal film patterns the substrate. In here, metal films formed on walls of resist patterns are removed, so that designed metal film patterns formed on trenches of resist patterns remain.

For comparison, the resist etching process shown in the schematic diagram of FIG. 2 is described briefly below. (a′) shows preparation a substrate.

(b′) shows forming metal film (e.g., electrode), and (c′) shows forming resist layer on the metal film. (d′) shows exposure through a mask, and (e′) shows development to form resist patterns. (f′) shows dry etch to remove bared metal film portion, and (g′) shows removing of remaining resist patterns on remaining metal film portion

Formation of Resist Layer

The composition of the invention is applied above a substrate. Before this, the substrate surface can be pre-treated, for example by 1,1,1,3,3,3-hexamethyldisilazane solution. The composition of the invention undergoes a reaction under irradiation and whose irradiated portion has an increased resistance against dissolution by a developer. A known method can be used for the application, for example spin coating. And the applied resist composition is baked to remove the solvent in the composition, thereby forming a resist layer. The baking temperature can vary depending on the composition to be used, but is preferably 70-150° C. (more preferably 90-150° C., further preferably 100 -140° C.). It can be carried out for 10-180 seconds, preferably for 30-90 seconds in the case of on a hot plate, or for 1 to 30 minutes in case of in a hot gas atmosphere (for example in a clean oven).

The formed resist layer has a thickness of 0.40-5.00 μm preferably (0.40-3.00 μm more preferably, 0.50-2.00 μm further preferably).

In the method for manufacturing resist patterns of the invention, an underlayer may be interposed between the substrate and the resist coating so that the substrate and the resist coating are not in direct contact with each other. Examples of the underlayer include a bottom anti-reflecting coating (BARC layer), an inorganic hard mask underlayer (such as a silicon oxide coating, silicon nitride coating, or silicon oxynitride coating), and an adhesive coating. The underlayer may consist of a single layer or a plurality of layers. Because of its good removability of the resist layer of the invention, it is preferable embodiment that the resist coating formed on a substrate without underlayer, and it can reduce the unintended risk that the underlayer (e.g., BARC) is dissolved during resist development that can cause process control difficult.

Other layer(s) (for example top anti-reflective coating, TARC) may be formed on the resist coating/layer.

Resist Patterning

The resist layer is exposed through a given mask. The wavelength of the light used for exposure is not particularly limited. The exposure is preferably performed with light having a wavelength of 13.5-365 nm (preferably 13.5-248 nm). KrF excimer laser (248 nm), ArF excimer laser (193 nm), or extreme ultraviolet light (13.5 nm) are preferred embodiments; KrF excimer laser is more preferred. These wavelengths may vary within ±1%. Because the resist patterns made by the composition of the invention can form good shape and can exhibit good removability, more fine designed mask can be used. For example, mask comprising on or less than 1.0 μm line-space width can be preferably used, and less than 1.0 μm line-space width can be more preferably used.

The exposure can, if desired, be followed by a post-exposure bake. The temperature for the post-exposure bake is selected from the range of 80-150° C., preferably 90-140° C., and the heating time for the post-exposure bake is selected from the range of 0.3-5 minutes, preferably 0.5-2 minutes. Next, development is performed with a developer. The unexposed portion of the resist layer of the invention is removed by the development, resulting in the formation of resist patterns. A 2.38 mass % (±1% concentration change accepted) aqueous TMAH solution is preferred as the developer used for the development in the resist patterns formation. An additive such as a surfactant can be added to the developer. The temperature of the developer is typically selected from the range of 5-50° C., preferably 25-40° C., and the development time is typically selected from the range of 10-300 seconds, preferably 30-90 seconds. As the developing method, known methods such as paddle development can be used. It is preferable that the resist layer is effectively removed and not remained at resist pattern trench portions.

After development, the resist patterns can be cleaned by water or cleaning solution as replacing developer with the water and/or cleaning solution. Then, the substrate can be dried, for example by a spin-dry method.

Manufacturing Metal Film Patterns On A Substrate

Metal is applied on resist patterns to form a metal film. Known methods can be used. Deposition and coating are preferable (vapor deposition is more preferable). Metal oxide is included in the metal, in the present specification. It is preferable that metal film has good conductivity. A single or plurality of mixed metals can be used. It is preferable that the thickness of formed metal film is effectively smaller than the thickness of resist pattern walls (preferably −80 to −20% of thickness, more preferably −70 to −30% of thickness), for making gap which resist layer remover can invade through to reach resist pattern walls.

Resist patterns and metal film on them are removed to obtain metal film patterns on the substrate (in narrow sense, this step can be called “lift-off”). Metal film formed on walls of resist patterns are removed, so that designed metal film patterns formed on trenches of resist patterns remain. Known methods can be used for this removing, for example resist layer remover. One embodiment of a resist layer remover is AZ Remover 700 (Merck Performance Materials ltd). Patterned metal film is preferably electrode on substrate, which can be used to make a device in later process.

Device Manufacturing

Subsequently, the substrate, if necessary, is further processed to form a device. Such further processing can be done by using a known method. After formation of the device, the substrate, if necessary, is cut into chips, which are connected to a leadframe and packaged with a resin. Preferably the device is a semiconductor device, a radio frequency module, solar cell chip, organic light emitting diode and inorganic light emitting diode. One preferable embodiment of the device of this invention is a semiconductor device. The other preferable embodiment of the device of this invention is a radio frequency module, which can be made of a transmitter (including IC chip) and a receiver.

### Examples

Hereinafter, the present invention will be described with working examples. These examples are given only for illustrative purpose and are not intended to limit the scope of the present invention. The term “part(s)” as used in the following description refers to part(s) by mass, unless otherwise stated.

Preparation Example 1 of working composition 1

Each of the components described below are prepared.

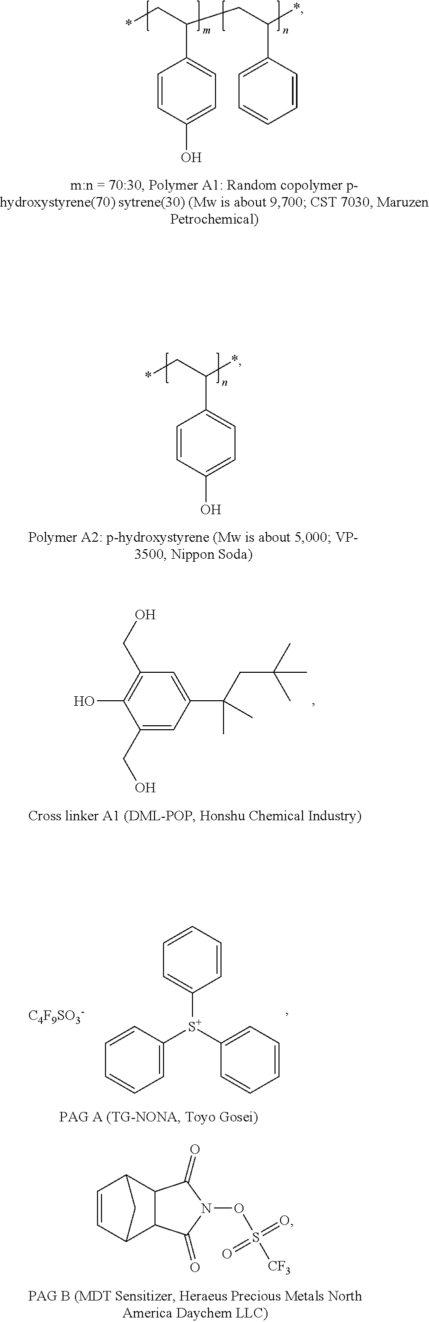

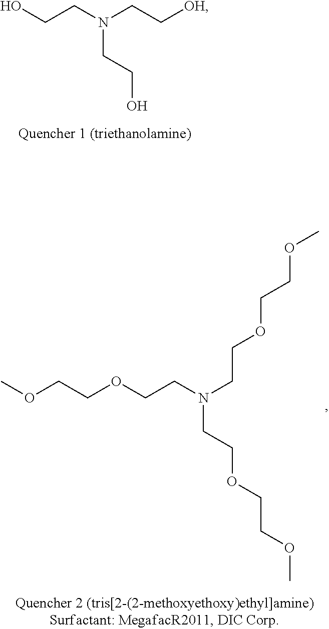

As the solvent, PGMEA is used.

Each component is added to the solvent. Respective ratios of Cross linker A1, PAG A, PAG B, Quencher and Surfactant are 10.66, 3.37, 0.62, 0.39 and 0.10 mass % comparing to sum of a single or plurality of polymer(s) as 100 mass %. This 100 mass % of polymer(s) is based on solid components amount.

Then the solution is stirred and confirmed that all components are dissolved. The solution is mixed and the solvent is added until total solid components concentration comes to 23.0 mass %. The resultant solution is filtrated by 0.1 μm capsule filter.

The obtained working composition is denoted by composition 1 in below Table 1-1.

Preparation Examples 2-15 of Working Compositions 2-15

Preparations are carried out in the same manners as in Preparation Example 1, except for changing component and/or amount as described in below Table 1-1.

Working composition 2-15 are obtained.

TABLE 1-1

| | Polymer | Polymer | Cross linker | PAG | PAG | | |
|---|---|---|---|---|---|---|---|
| | A1 | A2 | A1 | A | B | Quencher1 | Quencher2 |
| Comp. 1 | 50 | 50 | 10.66 | 3.37 | 0.62 | 0.39 | — |
| Comp. 2 | 50 | 50 | 10.66 | 3.37 | 0.93 | 0.39 | — |
| Comp. 3 | 50 | 50 | 10.66 | 3.37 | 1.86 | 0.39 | — |
| Comp. 4 | 50 | 50 | 10.66 | 2.81 | 1.55 | 0.39 | — |
| Comp. 5 | 50 | 50 | 10.66 | 2.25 | 1.24 | 0.39 | — |
| Comp. 6 | 50 | 50 | 10.66 | 3.37 | 1.86 | 0.49 | — |
| Comp. 7 | 50 | 50 | 10.66 | 3.37 | 1.86 | 0.59 | — |
| Comp. 8 | 50 | 50 | 10.66 | 1.12 | 1.24 | 0.39 | — |
| Comp. 9 | 50 | 50 | 10.66 | 1.69 | 1.24 | 0.39 | — |
| Comp. 10 | 60 | 40 | 10.66 | 1.12 | 1.24 | 0.39 | — |
| Comp. 11 | 60 | 40 | 7.99 | 1.12 | 1.24 | 0.39 | — |
| Comp. 12 | 60 | 40 | 10.66 | 3.37 | — | 0.39 | — |
| Comp. 13 | 70 | 30 | 10.66 | — | 1.24 | — | — |
| Comp. 14 | 70 | 30 | 10.66 | — | 9.31 | — | — |
| Comp. 15 | 50 | 50 | 6.93 | 1.69 | — | — | 0.49 |

In Table 1-1, “comp.” means “composition.” Same in hereinafter tables.

Example of Preparing A Substrate For Evaluating Working Composition 1

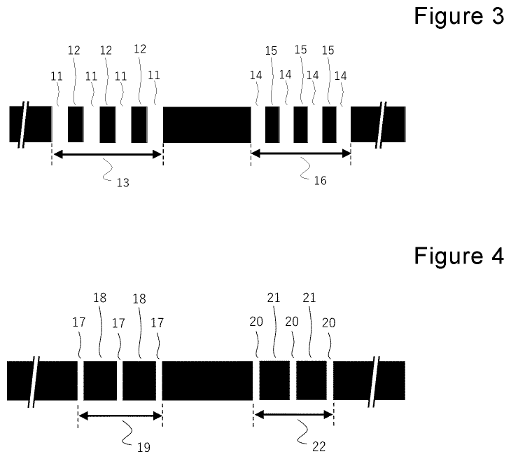

The substrate used for the following evaluations is prepared as shown below. The surface of a silicon substrate (SUMCO Corp., 8 inches) is treated with a 1,1,1,3,3,3-hexamethyldisilazane solution at 90° C. for 60 seconds. The working composition 1 is spin-coated thereon and soft-baked at 110° C. for 60 seconds, thereby forming a resist layer having a thickness of 1.30 μm on the substrate. This is exposed through a mask by an FPA-3000EX5 (Canon). The used mask has a region with plural 1.0 μm lines and line:space =1:1 (Dense region). And the mask has gradually narrowed lines and spaces regions located. Those lines width are 1.0 μm, 0.9 μm, 0.8 μm, 0.7 μm, 0.6 μm, 0.5 μm, 0.45 μm, 0.40 μm, 0.38 μm, 0.36 μm, 0.34 μm, 0.32 μm, 0.30 μm, 0.28 μm, 0.26 μm, 0.24 μm, 0.22 μm, 0.20 μm, 0.18 μm, 0.16 μm, 0.14 μm, 0.12 μm, and 0.10 μm. The mask has plural same width lines, and each line:space ratio are 1:1. For better understanding, the mask design is described in FIG. 3, which is not for limiting the scope of this invention but for illustrative purpose. An inexact reduction scale is used in FIG. 3 for better understanding.

Also, the used mask has a region with plural 1.0 μm lines and line:space=1:5 (Isolated region). And the mask has gradually narrowed lines and spaces regions located. Those lines width are 1.0 μm, 0.9 μm, 0.8 μm, 0.7 μm, 0.6 μm, 0.5 μm, 0.45 μm, 0.40 μm, 0.38 μm, 0.36 μm, 0.34 μm, 0.32 μm, 0.30 μm, 0.28 μm, 0.26 μm, 0.24 μm, 0.22 μm, 0.20 μm, 0.18 μm, 0.16 μm, 0.14 μm, 0.12 μm, and 0.10 μm. The mask has plural same width lines, and each line:space ratio are 1:5. For better understanding, the mask design is described in FIG. 4, which is not for limiting the scope of this invention but for illustrative purpose. An inexact reduction scale is used in FIG. 4 for better understanding.

This substrate is post-exposure baked (PEB) at 100° C. for 60 seconds. Thereafter, the resist layer is subjected to puddle development for 60 seconds using a 2.38% tetramethylammonium hydroxide (TMAH) aqueous solution. In a state of a puddle developing solution being paddled on the substrate, pure water is started to flow onto the substrate. And with rotating the substrate, the puddle developing solution is replaced with pure water. Then, the substrate is rotated at 2,000 rpm, thereby spin-dried.

Example of Preparing Substrates For Evaluating Working Composition 2-15

Each substrate preparation is carried out in the same manner as described above, except for changing working composition 1 with working composition 2-15.

Evaluation Example of Resist Pattern Shapes

The shapes of resist patterns exposed through 0.5 μm spaces in Dense region (line:space=1:1) on each above substrate are evaluated with a SEM instrument, SU8230 (Hitachi High-Technologies Corp.). Evaluation criteria are designated as follows.
A: Resist pattern collapse is not found.
B: Resist pattern collapse is found.

The evaluation results are shown in below Table 1-2.

Evaluation Example of Resolution

An exposure is conducted with the exposure amount which can reproduce 400 nm pattern by 400 nm slit (Line). Cross section SEM is observed to confirm pattern shape sequentially from 400 nm pattern to narrower ones. In here, resolution is the space width just before the one whose pattern collapse, or gap filled.

Evaluation criteria are designated as follows.

X: In Dense region, resolution is on or less than 340 nm.

Y: In Dense region, resolution is more than 340 nm.

X: In Isolated region, resolution is on or less than 300 nm.

Y: In Isolated region, resolution is more than 300 nm.

Total evaluation is classified as follows.

A: Both evaluation of Dense region and Isolated region are X.

B: At least one of evaluations of Dense and Isolated region is Y.

The evaluation results are shown in below Table 1-2.

TABLE 1-2

| | Pattern | Line:Space = 1:1 | | Line:Spece = 1:5 | | Total |
|---|---|---|---|---|---|---|
| | shape | (Dense) | | (Isolated) | | evaluation |
| Comp. 1 | A | 340 nm | X | 280 nm | X | A |
| Comp. 2 | A | 320 nm | X | 240 nm | X | A |
| Comp. 3 | A | 320 nm | X | 240 nm | X | A |
| Comp. 4 | A | 320 nm | X | 280 nm | X | A |
| Comp. 5 | A | 300 nm | X | 240 nm | X | A |
| Comp. 6 | A | 300 nm | X | 220 nm | X | A |
| Comp. 7 | A | 300 nm | X | 220 nm | X | A |
| Comp. 8 | A | 340 nm | X | 240 nm | X | A |
| Comp. 9 | A | 340 nm | X | 240 nm | X | A |
| Comp. 10 | A | 300 nm | X | 240 nm | X | A |
| Comp. 11 | A | 280 nm | X | 260 nm | X | A |
| Comp. 12 | A | 400 nm | Y | 360 nm | Y | B |
| Comp. 13 | A | 380 nm | Y | 180 nm | X | B |
| Comp. 14 | A | 380 nm | Y | 180 nm | X | B |
| Comp. 15 | A | 340 nm | X | 240 nm | X | A |

Preparation Example 16-20 of Working Composition 16-20, and Reference Preparation Example 1 of Reference Composition 1

Preparations are carried out in the same manners as in Preparation Example 1, except for changing component and/or amount as described in below Table 2-1, and total solid components concentration comes to 13.0 mass %.

Working composition 16-20 and reference composition 1 are obtained.

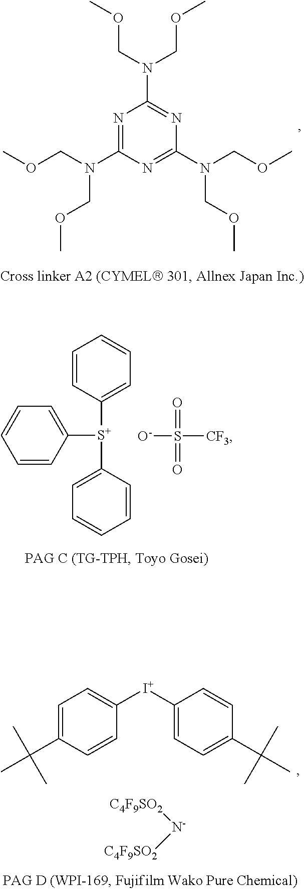

TABLE 2-1

| | Polymer | Polymer | Cross linker | Cross linker | PAG | PAG | PAG | |
|---|---|---|---|---|---|---|---|---|
| | A1 | A2 | A1 | A2 | A | C | D | Quencher1 |
| Comp. 16 | 40 | 60 | 11.19 | 1.93 | 10.8 | — | — | — |
| Comp. 17 | 65 | 35 | 7.99 | — | 3.37 | — | — | 0.392 |
| Comp. 18 | 60 | 40 | 7.99 | — | 3.37 | — | — | 0.392 |
| Comp. 19 | 55 | 45 | 7.99 | — | 3.37 | — | — | 0.392 |
| Comp. 20 | 70 | 30 | 9.32 | — | — | 0.83 | 0.98 | 0.149 |
| Ref. comp. 1 | — | 100 | 11.19 | 1.93 | 10.8 | — | — | — |

In Table 2-1, “ref.” means “reference”. “Same in hereinafter tables.”

Example of Preparing Substrates for Evaluating Working Composition 16

The substrate used for following evaluations is prepared as shown below. BARC composition AZ KrF-17B (Merck Performance Materials ltd., hereinafter denoted as MPM ltd.) is spin-coated on the surface of a silicon substrate (SUMCO Corp., 8 inches), and baked at 180 C degree for 60 seconds to obtain BARC coating with 38 nm thickness. The working composition 16 is spin-coated thereon and soft-baked at 110° C. for 60 seconds, thereby forming a resist layer having a thickness of 0.50 μm on the substrate.

An exposure and later treatments are carried out in the same manner as described in Example of preparing a substrate for evaluating working composition 1, except for changing mask with only Dense region. Then, a substrate for evaluating working composition 16 is obtained.

Example of Preparing Substrates for Evaluating Working Composition 17-20 and Reference Composition 1

Each substrate preparation is carried out in the same manner as described in Example of preparing a substrate for evaluating working composition 16, except for changing working composition 16 with working composition 17-20 and reference composition 1

Evaluation Example of Resist Pattern Shapes

The shapes of resist patterns exposed through 0.25 μm spaces in Dense region (line:space=1:1) on each substrate of working composition 16-20 and reference composition 1 are evaluated with a SEM instrument, SU8230.

Evaluation criteria are designated as follows.
A: Resist pattern collapse is not found.
B: Resist pattern collapse is found.

The evaluation results are shown in below Table 2-2.

Evaluation Example of Resolution

An exposure is conducted with the exposure amount which can reproduce 300 nm pattern by 300 nm slit (Line). Cross section SEM is observed to confirm pattern shape sequentially from 400 nm pattern to narrower ones. In here, resolution is the space width just before the one whose space collapse.

Evaluation criteria are designated as follows.
A: Resolution is on or less than 260 nm.
B: Resolution is more than 260 nm.

TABLE 2-2

| | |
|---|---|
| | Line:Space = 1:1 |
| Pattern shape | (Dense) |

| | | | |
|---|---|---|---|
| Comp. 16 | A | 220 nm | A |
| Comp. 17 | A | 180 nm | A |
| Comp. 18 | A | 200 nm | A |
| Comp. 19 | A | 200 nm | A |
| Comp. 20 | A | 180 nm | A |
| Ref. comp. 1 | A | 300 nm | B |

The resist layers made from working compositions exhibit better resolution than the one made from reference composition.

Preparation Example 21-24 of Working Composition 21-24

Preparations are carried out in the same manners as in Preparation Example 1, except for changing component and/or amount as described in below Table 3-1, and total solid components concentration comes to 24.0 mass %. Working composition 21-24 are obtained.

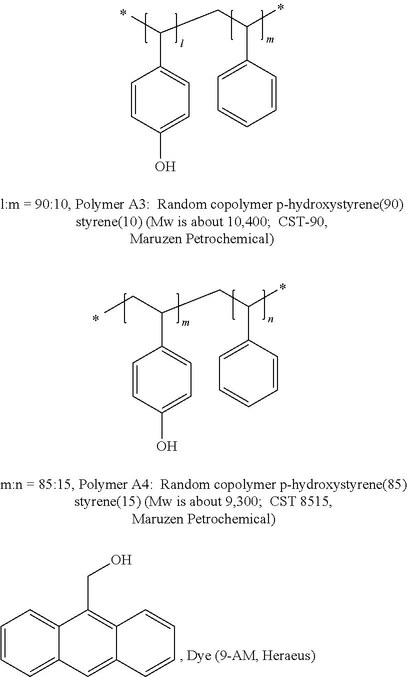

TABLE 3-1

| | Polymer | Polymer | Cross linker | Cross linker | PAG | PAG | | |
|---|---|---|---|---|---|---|---|---|
| | A3 | A4 | A1 | A2 | A | B | Quencher1 | Dye |
| Comp. 21 | 100 | — | 5.6 | 1 | 1 | 5 | 0.8 | 0.8 |
| Comp. 22 | 50 | 50 | 5.6 | 1 | — | 7.5 | — | — |
| Comp. 23 | 50 | 50 | 5.6 | 1 | — | 7.5 | — | 0.8 |
| Comp. 24 | 50 | 50 | 5.6 | 1 | — | 7.5 | — | 1.5 |

Example of Preparing Substrates for Evaluating Working Composition 21-24

Each substrate preparation is carried out in the same manner as described in Example of preparing a substrate for evaluating working composition 1, except for changing working composition 1 with working composition 21-24, mask with only Dense region, and forming a resist layer having a thickness of 1.50 μm on the substrate.

Evaluation Example of Resist Pattern Shapes

The shapes of resist patterns exposed through 0.7 μm spaces in Dense region (line:space=1:1) on each substrate of working composition 21-24 are evaluated with a SEM instrument, SU8230. Evaluation criteria are designated as follows.
A: Resist pattern collapse is not found.
B: Resist pattern collapse is found.

The evaluation results are shown in below Table 3-2.

Evaluation Example of Removability

20 mm×20 mm segments cut from each substrate of working composition 21-24 are prepared. These segments are baked at 110 ° C. for 90 seconds. Each segment is placed on the petri dish, far enough from the dish center. A resist layer remover (AZ Remover 700, MPM ltd) is slowly added in a petri dish. With mixing by a stirrer, the solution is heated until 70° C. After 10 minutes mixing the solution, the segment is taken out. And the resist layer remover is washed off by a sufficient pure-water. And the segment is dried by a N₂ gas spraying

The place resist patterns located before removing is observed by an optical microscope, from 1.0 μm line-space exposed ones to gradually narrower ones. Evaluation criteria are designated as follows.
A: On and less than 0.7 μm line-space exposed resist patterns are removed clearly.
B: More than 0.7 μm line-space exposed resist patterns are removed clearly.

The evaluation results are shown in above Table 3-2.

TABLE 3-2

| | Pattern shape | Removability |
|---|---|---|
| Comp. 21 | A | A |
| Comp. 22 | A | A |
| Comp. 23 | A | A |
| Comp. 24 | A | A |

Resist patterns made from the working example compositions can be removed clearly.

### REFERENCE SIGNS LIST

1. Substrate

2. Resist layer

3. Mask

4. Radiation

5. Metal film

6. Substrate

7. Metal film

8. Resist layer

9. Mask

10. Radiation

11. 1.0 μm width line

12. 1.0 μm width space

13. A region with 1.0 μm width lines and line:space=1:1

14. 0.9 μm width line

15. 0.9 μm width space

16. A region with 0.9 μm width lines and line:space=1:1

17. 1.0 μm width line

18. 5.0 μm width space

19. A region with 1.0 μm width lines and line:space=1:5

20. 0.9 μm width line

21. 4.5 μm width space

22. A region with 0.9 μm width lines and line:space=1:5

1.-11. (canceled)

12. A negative tone lift off resist composition comprising a single or plurality of (A) alkali soluble resin, and a single or plurality of (B) photo acid generator; wherein
(A) alkali soluble resin comprises (A1) resin and/or (A2) resin;
(B) photo acid generator comprises (B1) onium salt and/or (B2) sulfonyl compound;
with the proviso that
(i) in case the negative tone lift off resist composition comprises a single of (A) alkali soluble resin, the negative tone lift off resist composition comprises a plurality of (B) photo acid generators, and
(ii) in case the negative tone lift off resist composition comprises a single of (B) photo acid generator, the negative tone lift off resist composition comprises a plurality of (A) alkali soluble resins;
(A1) resin is represented by below formula (A1); 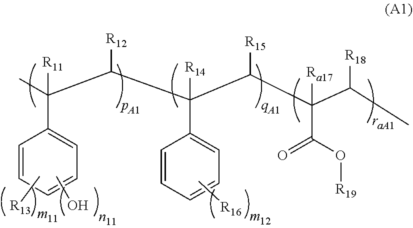
R₁₁, R₁₂, R₁₄, R₁₅, R₁₇ and R₁₈ are each independently hydrogen, C₁₋₆ alkyl, carboxyl, halogen or cyano,
R₁₃ and R₁₆ are each independently C₁₋₆ alkyl, C₁₋₆ alkoxy, halogen or cyano,
R₁₉ is C₁₋₁₅ alkyl or C₁₋₁₅ alkoxy, wherein the alkyl portion of R₁₉ can form a saturated ring and/or an unsaturated ring,
m₁₁ is a number of 0-4, n₁₁ is a number of 1-3, m₁₁+n₁₁≤5, m₁₂ is a number of 0-5,
p_{A1}, q_{A1} and r_{A1} are repeating numbers, [p_{A1}/(p_{A1}+q_{A1}+r_{A1})] is 30-98%, [q_{A1}/(p_{A1}+q_{A1}+r_{A1})] is 0-70%, [r_{A1}/(p_{A1}+q_{A1}+r_{A1})] is 0-70%;
(A2) resin is represented by below formula (A2); 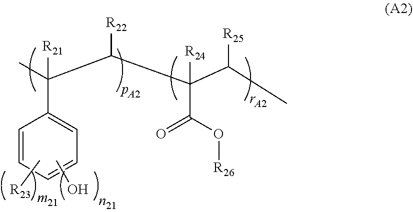
R₂₁, R₂₂, R₂₄ and R₂₅ are each independently hydrogen, C₁₋₆ alkyl, carboxyl, halogen or cyano,
R₂₃ is C₁₋₆ alkyl, C₁₋₆ alkoxy, halogen or cyano,
R₂₆ is C₁₋₁₅ alkyl or C₁₋₁₅ alkoxy, wherein the alkyl portion of R₂₆ can form a saturated ring and/or an unsaturated ring,
m₂₁ is a number of 0-4, n21 is a number of 1-3, m₂₁+n₂₁≤5,
p_{A2} and r_{A2} are repeating numbers, [p_{A2}/(p_{A2}+r_{A2})] is 30-100%, [r_{A2}/(p_{A2}+r_{A2})] is 0-70%;
(B1) onium salt is represented by below formula (B1);
[Bₘ₊ cation] [B^{m-} anion] (B1)
B^{m+} cation is represented by below formula (B1)-C1 and/or formula (B1)-C2, having m valences as whole, m=1-3; 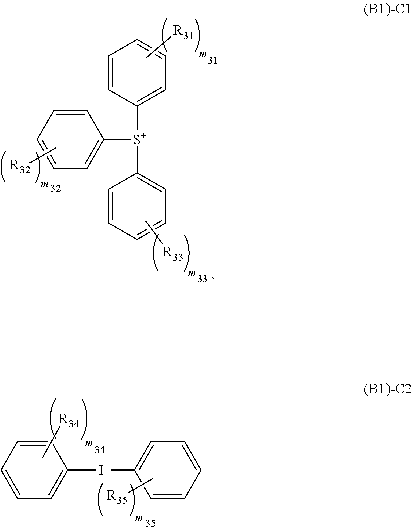
R₃₁, R₃₂, R₃₃, R₃₄ and R₃₅ are each independently C₁₋₆ alkyl, C₁₋₆ alkoxyl or C₆₋₁₂ aryl, m₃₁, m₃₂, m₃₃, m₃₄ and m₃₅ are each independently numbers of 0-3;
B^{m-} anion is represented by below formula (B1)-A1, (B1)-A2 and/or (B1)-A3; 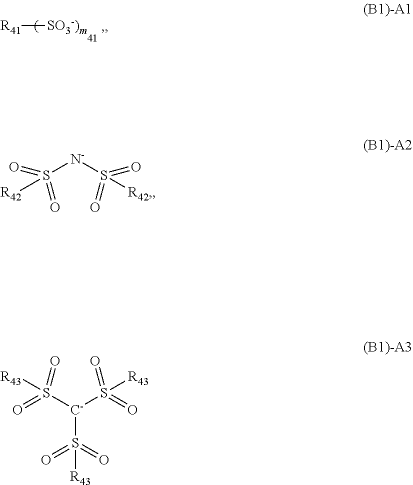
R₄₁, R₄₂ and R₄₃ are each independently C₆₋₁₂ aryl unsubstituted or substituted by C₁₋₆ alkyl, C₁₋₁₂ alkyl unsubstituted or substituted by halogen or carbonyl, m₄₁=1 or 2;
(B2) sulfonyl compound is represented by below formula (B2)-1 or (B2-2); 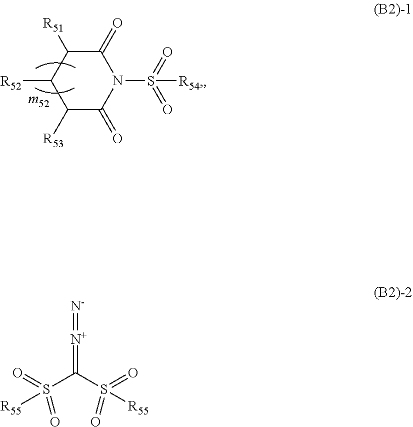
R₅₁, R₅₂ and R₅₃ are each independently hydrogen, C₁₋₆ alkyl, C₁₋₆ alkoxyl or C₆₋₁₂ aryl, wherein the alkyl portion of R₅₁, R₅₂ and R₅₃ can bind to each other to constitute cycloalkyl or aryl,
m₅₂=0 or 1,
R₅₄ is C₁₋₆ alkyl unsubstituted or substituted by halogen,
R₅₅ are each independently C₅₋₁₂ cycloalkyl or C₆₋₁₂ aryl.

13. The negative tone lift off resist composition according to claim 12, further comprising (C) solvent.

14. The negative tone lift off resist composition according to claim 13, wherein said (C) solvent is selected from the group consisting of aliphatic hydrocarbon solvent, aromatic hydrocarbon solvent, monoalcohol solvent, polyol solvent, ketone solvent, ether solvent, ester solvent, nitrogen-containing solvent, sulfur-containing solvent, and any combination of any of these.

15. The negative tone lift off resist composition according to claim 12, wherein the mass ratio of the (A) alkali soluble resin to the total mass of the negative tone lift off resist composition is 5 - 50 mass %; and
the mass ratio of (B) photo acid generator to the mass of (A) alkali soluble resin is 1-20 mass.

16. The negative tone lift off resist composition according to claim 14, wherein the mass ratio of the (A) alkali soluble resin to the total mass of the negative tone lift off resist composition is 5-50 mass %; and
the mass ratio of (B) photo acid generator to the mass of (A) alkali soluble resin is 1-20 mass %; and
the mass ratio of the (C) solvent to the total mass of the negative tone lift off resist composition is 30-94 mass %.

17. The negative tone lift off resist composition according to claim 12, further comprising (D) cross linker; wherein (D) cross linker comprises at least one element selected from the group consisting of aryl compound, melamine compound, guanamine compound, glycoluril compound, urea compound epoxy compound, thioepoxy compound, isocyanate compound, azide compound and alkenyl compound; and each compound are unsubstituted or substituted by at least one group selected from a hydroxyl group, a methylol group, an alkoxymethyl group, and an acyloxymethyl group.

18. The negative tone lift off resist composition according to claim 12 further comprising (D) cross linker, wherein the (D) cross linker comprises (D1) cross linker represented by formula (D1) and/or (D2) cross linker represented by formula (D2); 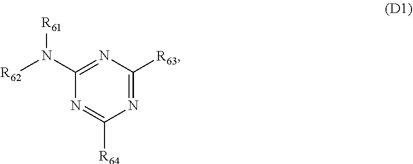
R₆₁ is C₂₋₈ alkoxylalkyl, R₆₂ is C₂₋₈ alkoxylalkyl,
R₆₃ is C₆₋₁₀ aryl unsubstituted or substituted by C₁₋₆ alkyl, C₁₋₈ alkyl unsubstituted or substituted by C₁₋₆ alkyl, or −NR₆₁R₆₂,
R₆₄ is C₆₋₁₀ aryl unsubstituted or substituted by C₁₋₆ alkyl, C₁₋₈ alkyl unsubstituted or substituted by C₁₋₆ alkyl, or —NR₆₁R₆₂, 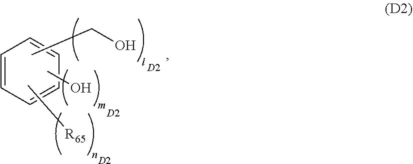
R₆₅ is C₁₋₂₀ alkyl unsubstituted or substituted by C₁₋₆ alkyl,
I_{D2} is 1, 2, 3 or 4, m_{D2} is 0, 1 or 2, n_{D2} is 0, 1 or 2, and I_{D2}+m_{D2}+n_{D2}≤6.

19. The negative tone lift off resist composition according to claim 18, wherein the mass ratio of (D) cross linker to the mass of (A) alkali soluble resin is 1-20 mass %;
the mass ratio of (D1) cross linker to the mass of (A) alkali soluble resin is 0.10-8 mass %; and
the mass ratio of the (D2) cross linker to the mass of (A) alkali soluble resin is 0.50-40 mass %.

20. The negative tone lift off resist composition according to claim 12, wherein the weight average molecular weight (Mw) of the (A) alkali soluble resin is 2,000 to 100,000.

21. The negative tone lift off resist composition according to claim 12, wherein the weight average molecular weight (Mw) of the (A1) resin is 5,000 to 100,000.

22. The negative tone lift off resist composition according to claim 12, wherein the weight average molecular weight (Mw) of the (A2) resin is 2,000 to 20,000.

23. The negative tone lift off resist composition according to claim 12, further comprising at least one additive selected from the group consisting of a quencher, a surfactant, dye, a contrast enhancer, acid, a radical generator, an agent for enhancing adhesion to substrates, base, a surface leveling agent, and an anti-foaming agent.

24. A method for manufacturing a resist pattern, comprising:
forming a coating of the negative tone lift off resist composition according to claim 12 above a substrate;
baking the resist composition to form a resist layer;
exposing the resist layer;
developing the resist layer to form resist patterns.

25. The method for manufacturing resist pattern according to claim 24, wherein the exposing uses 13.5-365 nm wavelength light.

26. A method for manufacturing metal film patterns on a substrate, comprising :
manufacturing the resist pattern according to claim 24, forming metal film on the resist patterns; and
removing remained resist patterns and metal film on them.

27. A method for manufacturing a device, comprising a manufacturing method of resist pattern or metal film patterns on a substrate according to claim 24.
